(19) United States
(12) Patent Application Publication
(10) Pub. No.: US 2025/0275269 A1
(43) Pub. Date: Aug. 28, 2025

(54) IMAGE SENSOR AND METHOD FOR FABRICATING THE SAME

(71) Applicant: Samsung Electronics Co., Ltd., Suwon-si (KR)

(72) Inventor: Haewon LEE, Suwon-si (KR)

(73) Assignee: Samsung Electronics Co., Ltd., Suwon-si (KR)

(21) Appl. No.: 19/009,508

(22) Filed: Jan. 3, 2025

(30) Foreign Application Priority Data
Feb. 28, 2024 (KR) 10-2024-0029257

(51) Int. Cl. H10F 39/00

(52) U.S. Cl. CPC H10F 39/802; H10F 39/011; H10F 39/014; H10F 39/8037; H10F 39/807

(57) ABSTRACT

An image sensor comprises a substrate region including a photoelectric conversion region, a transfer gate electrode including a buried region buried in the substrate region and a capping region on the buried region, a floating diffusion region within the substrate region and least partially overlapping the buried region along a horizontal direction parallel to a top surface of the substrate region, a floating diffusion pattern on the first floating diffusion region and least partially overlapping the capping region along the horizontal direction, and a transfer gate spacer between the transfer gate electrode and the floating diffusion pattern.

### CROSS-REFERENCE TO RELATED APPLICATIONS

The application claims benefit of priority under 35 U.S.C. § 119 to Korean Patent Application No. 10-2024-0029257, filed on Feb. 28, 2024, in the Korean Intellectual Property Office, the disclosures of which are incorporated by reference herein in their entireties.

### BACKGROUND

The present inventive concepts relate generally to image sensors and methods of manufacturing the image sensors.

Image sensors are devices that convert optical image signals into electrical signals, and include charge coupled device (CCD) image sensors and complementary metal oxide semiconductor (CMOS) image sensors. The image sensors include a plurality of pixels. Each pixel includes a light-receiving region that receives incident light and converts it into an electrical signal, and a pixel circuit that outputs a pixel signal using charges generated in the light-receiving region.

To prevent gate-induced leakage current, a transfer gate electrode and a floating diffusion region may be spaced apart from each other at least a certain level (e.g. a certain magnitude of spacing distance). Accordingly, the image sensor may not have a required (or sufficient) fill factor (e.g., a ratio of light sensitive area of the plurality of pixels of the image sensor to a total area of the plurality of pixels of the image sensor).

### SUMMARY

Some example embodiments provide an image sensor with improved fill factor (e.g., an increased ratio of light sensitive area of the plurality of pixels of the image sensor to a total area of the plurality of pixels of the image sensor).

Some example embodiments provide an image sensor with improved charge trapping characteristics.

Some example embodiments provide a method for fabricating an image sensor with improved fill factor.

Some example embodiments provide a method for fabricating an image sensor with improved charge trapping characteristics.

According to some example embodiments, an image sensor may include a substrate region including a photoelectric conversion region, a transfer gate electrode including a buried region within the substrate region and a capping region on the buried region, a floating diffusion region within the substrate region and at least partially overlapping the buried region along a horizontal direction parallel to a top surface of the substrate region, a floating diffusion pattern on the floating diffusion region and at least partially overlapping the capping region along the horizontal direction, and a transfer gate spacer between the transfer gate electrode and the floating diffusion pattern.

According to some example embodiments, a method for manufacturing an image sensor may include forming a substrate region including a photoelectric conversion region, forming a floating diffusion region at an upper portion of the substrate region, forming a floating diffusion pattern on the floating diffusion region, heat treating the floating diffusion pattern, forming a transfer gate electrode including a buried region within the substrate region and a capping region on the buried region, and forming a transfer gate spacer on a lateral surface of the transfer gate electrode facing the floating diffusion pattern. The floating diffusion region may at least partially overlap the buried region along a horizontal direction parallel to a top surface of the substrate region. The floating diffusion pattern may at least partially overlap the capping region along the horizontal direction.

According to some example embodiments, an image sensor may include a device layer, a wiring layer electrically connected to the device layer, and a lens layer configured to focus incident light on the device layer. The device layer may include a substrate region having a photoelectric conversion region, a transfer gate electrode including a buried region within the substrate region and a capping region on the buried region, a floating diffusion region within the substrate region and at least partially overlapping the buried region along a horizontal direction parallel to a top surface of the substrate region, a floating diffusion pattern on the floating diffusion region and at least partially overlapping the capping region along the horizontal direction, and a transfer gate spacer between the transfer gate electrode and the floating diffusion pattern.

Additional aspects will be set forth in part in the description which follows and, in part, will be apparent from the description, or may be learned by practice of the presented example embodiments.

### BRIEF DESCRIPTION OF THE DRAWINGS

The above and other aspects, features, and advantages of in some example embodiments of the present inventive concepts will be more apparent from the following description taken in conjunction with the accompanying drawings, in which:

FIG. 1 is a block diagram of an image sensor according to some example embodiments.

FIG. 2 is a plan view of the pixel array of FIG. 1 according to some example embodiments.

FIG. 3 is an equivalent circuit diagram of the pixel group of FIG. 1 according to some example embodiments.

FIGS. 4A and 4B are cross-sectional views of an image sensor according to some example embodiments.

FIGS. 5, 6, 7, 8, 9, 10, 11, 12, and 13 are lines are cross-sectional views for explaining a method of manufacturing an image sensor according to some example embodiments.

FIG. 14 is a cross-sectional view showing an image sensor according to some example embodiments.

FIG. 15 is a cross-sectional view showing an image sensor according to some example embodiments.

FIG. 16 is a cross-sectional view showing an image sensor according to some example embodiments.

### DETAILED DESCRIPTION

Hereinafter, example embodiments of the present inventive concepts will be described clearly and in detail so that a person skilled in the art may easily implement the present inventive concepts.

In order to clearly explain the present inventive concepts in the drawings, parts that are not related to the description are omitted, and similar parts are given similar reference numerals throughout the specification. In methods described with reference to the drawings, the order of operations of the methods may be changed, several operations may be merged, certain operations may be divided, and certain operations may not be performed.

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of +10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., +10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., +10%) around the stated elements and/or properties thereof.

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

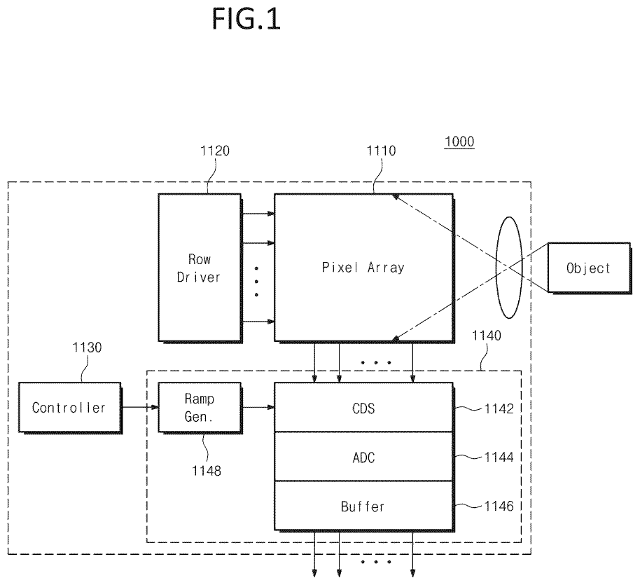

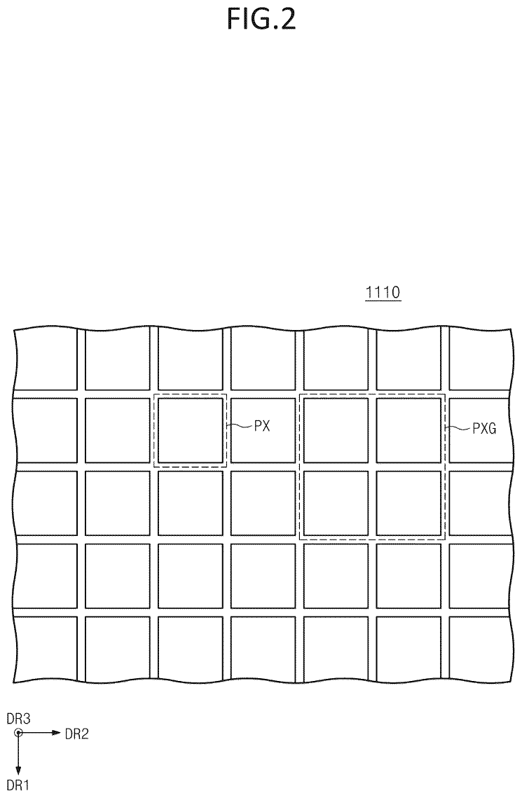

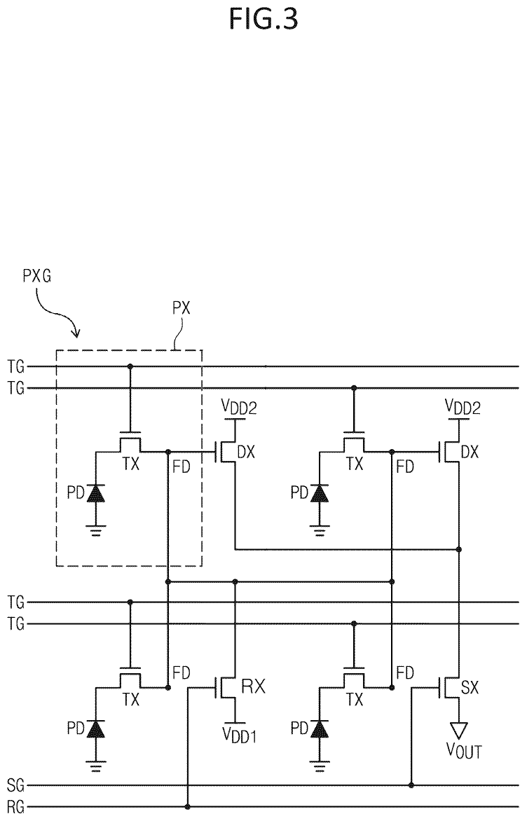

FIG. 1 is a block diagram of an image sensor according to some example embodiments. FIG. 2 is a plan view of a pixel array of FIG. 1 according to some example embodiments. FIG. 3 is an equivalent circuit diagram of a pixel group of FIG. 1 according to some example embodiments.

Referring to FIG. 1, an image sensor 1000 may be provided. The image sensor 1000 may be mounted in an electronic device having an image or light sensing function. For example, the electronic device may be a camera, a smartphone, a wearable device, the Internet of Things (IoT), a tablet PC (Personal Computer), a PDA (Personal Digital Assistant), a PMP (portable multimedia player), or a navigation device. The image sensor 1000 may be mounted in electronic devices provided as components in various devices (e.g., vehicles, furniture, manufacturing facilities, doors, various measuring devices, etc.).

The image sensor 1000 may include a control unit including a pixel array 1110, a controller 1130, a row driver 1120, and a pixel signal processor 1140.

As shown in FIG. 2, the pixel array 1110 may include a plurality of pixels two-dimensionally arranged along a first direction DR1 and a second direction DR2. The second direction DR2 may be different from the first direction DR1. The second direction DR2 may be perpendicular to the first direction DR1. The plurality of pixels may be arranged in a regular pattern to generate a high-quality image. For example, the plurality of pixels may be arranged in a Bayer pattern or a chess mosaic pattern. When the plurality of pixels have a Bayer pattern, the pixels in the pixel array 1110 may receive red light, green light, and blue light, respectively. In some example embodiments, the plurality of pixels may receive cyan light, magenta light, and yellow light. Each of the pixels may include a photoelectric conversion device. The photoelectric conversion device may absorb light to generate charge carriers (electrons or holes). For example, the photoelectric conversion device may include photodiodes, phototransistors, photogates, pinned photodiodes, or a combination thereof. Output voltages of the plurality of pixels may be determined based on the generated charge carriers.

The pixel array 1110 may include a pixel group PXG. The pixel group PXG may be a set of pixels PX sharing a reset transistor RX, a selection transistor SX, and a source follower transistor DX. Although the pixel group PXG is illustrated as being composed of four pixels PX, in some example embodiments the pixel group PXG may include less than or more than four pixels PX.

The pixel array 1110 may be driven by receiving a plurality of driving signals, such as a row selection signal, a reset signal, and a charge transfer signal, from the row driver 1120. The row driver 1120 may provide a plurality of driving signals to the pixel array 1110 for driving the plurality of pixels. In some example embodiments, the driving signals may be provided for each row of the pixel array 1110. Pixels belonging to one row of the pixel array 1110 selected by the driving signals of the row driver 1120 may be simultaneously activated by a signal output from the row driver 1120. The pixels belonging to the selected row may provide output voltages according to absorbed light to output lines of corresponding columns. In some example embodiments, the pixels belonging to the selected one row may provide the output voltages together. The output voltages may be provided to correlated double sampler 1142.

The pixel signal processor 1140 may include a correlated double sampler (CDS) 1142, an analog-to-digital converter (ADC) 1144, and a buffer 1146. The correlated double sampler 1142 may sample and hold the output voltages provided by the pixel array 1110. The correlated double sampler 1142 can reduce noise and improve Signal Noise Ratio (SNR). The correlated double sampler 1142 can be configured to remove noise voltages from the output voltages of the pixel. For example, the correlated double sampler 1142 may double sample a specific noise level and a signal level by an output signal, and output a difference level corresponding to a difference between the noise level and the signal level. The correlated double sampler 1142 may output a result based on ramp signals generated by a ramp signal generator 1148.

The analog-to-digital converter 1144 may convert an analog signal corresponding to the difference level received from the correlated double sampler 1142 into a digital signal. The buffer 1146 may latch digital signals, and the latched signals may be sequentially output to the outside of the image sensor 1000 and transferred to an image processor (not shown).

The controller 1130 may control the row driver 1120 so that the pixel array 1110 absorbs light to accumulate charge carriers, temporarily stores the accumulated charge, and outputs an electrical signal according to the accumulated charge to the outside of the pixel array 1110. Also, the controller 1130 may control the pixel signal processor 1140 to measure an output voltage provided by the pixel array 1110.

As described herein, any devices, systems, modules, portions, units, controllers, circuits, and/or portions thereof according to any of the example embodiments, and/or any portions thereof (including, without limitation, the image sensor 1000, the pixel array 1110, the row driver 1120, the controller 1130, the pixel signal processor 1140, the correlated double sampler 1142, the ADC 1144, the buffer 1146, the ramp signal generator 1148, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Referring to FIG. 3, each pixel of the plurality of pixels PX may include a photoelectric conversion device PD, a transfer transistor TX, and a floating diffusion region FD. The photoelectric conversion device PD may generate and accumulate photo charges in proportion to the amount of light incident from the outside, and may include a photodiode, a phototransistor, a photogate, a pinned photodiode, or a combination thereof.

The transfer transistor TX may include a transfer gate TG. The transfer gate TG may transfer charge carriers generated by the photoelectric conversion device PD to the floating diffusion region FD. A transfer control voltage provided from the row driver 1120 may be applied to the transfer gate TG. For example, a channel may be formed between the photoelectric conversion device PD and the floating diffusion region FD by the transfer control voltage applied to the transfer gate TG. Charge carriers generated by the photoelectric conversion device PD may move to the floating diffusion region FD along the channel between the photoelectric conversion device PD and the floating diffusion region FD. A drain terminal of the transfer transistor TX may be electrically connected to the floating diffusion region FD, and a source terminal of the transfer transistor TX may be electrically connected to the photoelectric conversion device PD.

The floating diffusion region FD may receive, accumulate, and store charges generated by the photoelectric conversion device PD. The source follower transistor DX may be controlled according to the amount of charge accumulated in the floating diffusion region FD. A gate terminal of the source follower transistor DX may be electrically connected to the floating diffusion region FD. A second power voltage VDD2 may be applied to a drain terminal of the source follower transistor DX. A source terminal of the source follower transistor DX may be electrically connected to a drain terminal of the selection transistor SX. The source follower transistor DX may be a source follower buffer amplifier that outputs a current proportional to the amount of charge accumulated in the floating diffusion region FD.

The reset transistor RX may periodically reset charges accumulated in the floating diffusion region FD. A gate terminal of the reset transistor RX may be electrically connected to a reset signal line RG. A drain terminal of the reset transistor RX may be connected to the floating diffusion region FD. A first power voltage VDD1 may be applied to a source terminal of the reset transistor RX. In some example embodiments, the first power voltage VDD1 may be equal or substantially equal to the second power voltage VDD2. When the reset transistor RX is turned on, the first power voltage VDD1 applied to the source terminal of the reset transistor RX is transferred to the floating diffusion region FD. When the reset transistor RX is turned on, charges accumulated in the floating diffusion region FD are discharged to reset the floating diffusion region FD. When electrons are charge carriers, the voltage of the floating diffusion region FD may decrease as electrons are accumulated in the floating diffusion region FD. When the reset transistor RX is turned on, electrons of the floating diffusion region FD are discharged to the outside, and the voltage of the floating diffusion region FD may increase to the first power voltage VDD1. As the first power voltage VDD1 is applied to the floating diffusion region FD, the first power voltage VDD1 may be applied to the gate terminal of the source follower transistor DX to reset the output of the source follower transistor DX.

The selection transistor SX may select a plurality of pixels PX in each row. The selection transistor SX may transfer current generated by the source follower transistor DX included in each of the selected pixels to an output line (not shown). A drain terminal, a source terminal, and a gate terminal of the selection transistor SX may be electrically connected to the source terminal, the output line, and the row selection line SG of the source follower transistor DX, respectively. A selection control signal applied from the row selection line SG may be applied to the gate terminal of the selection transistor SX to output a signal generated by the source follower transistor DX to the output line.

As shown in FIG. 3, in some example embodiments a pixel group PXG may include multiple pixels PX sharing a floating diffusion node FD and further sharing a reset transistor RX, a selection transistor SX, and at least one of a set of source follower transistor DX.

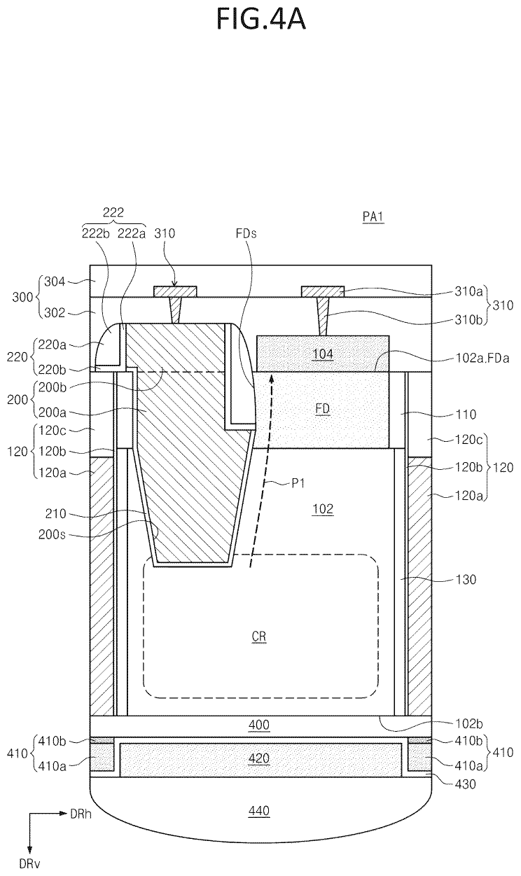

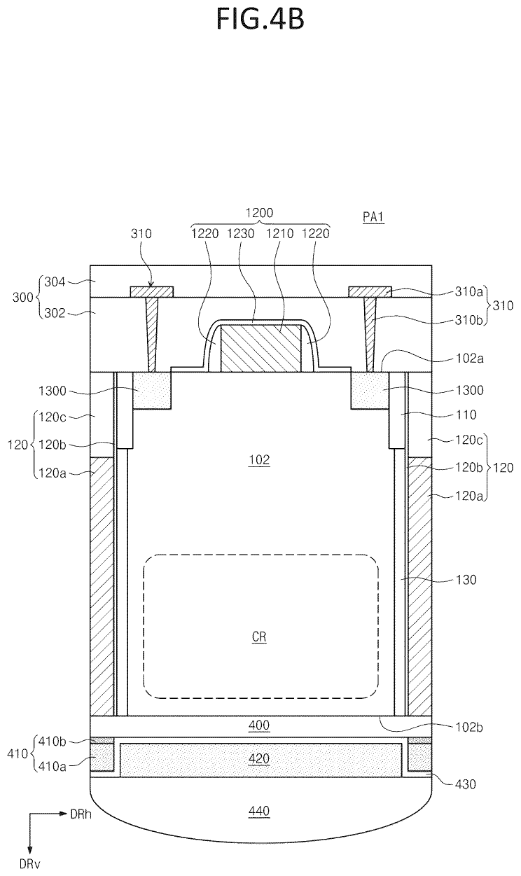

FIGS. 4A and 4B are cross-sectional views of an image sensor according to some example embodiments.

Referring to FIGS. 4A and 4B, a substrate region 102 may be provided. The substrate region 102 may be referred to herein interchangeably as a substrate, a semiconductor substrate, or the like. The substrate region 102 may include a semiconductor material. For example, the substrate region 102 may include silicon (Si), germanium (Ge), or silicon-germanium (Si—Ge). The substrate region 102 may have a first conductivity type. For example, the first conductivity type may be p-type or n-type. When the conductivity type of the substrate region 102 is p-type, the substrate region 102 may be a silicon (Si) region containing a group 3 element or a group 2 element as an impurity. For example, the group 3 element may include boron (B), aluminum (Al), gallium (Ga), or indium (In). When the conductivity type of the substrate region 102 is n-type, the substrate region 102 may be a silicon (Si) region containing a group 5 element, a group 6 element, or a group 7 element as an impurity. For example, the group 5 element may include phosphorus (P), arsenic (As), or antimony (Sb). Hereinafter, the impurity that causes the substrate region 102 to have the first conductivity type and a second conductivity type may be referred to as a first impurity and a second impurity, respectively. The first impurity may have the conductivity type opposite to that of the second impurity. When the first conductivity type is p-type or n-type, the second conductivity type may be n-type or p-type, respectively. For brevity of explanation, hereinafter the first conductivity type is described as p-type, and the second conductivity type is described as n-type. The substrate region 102 may be an epitaxial layer formed through an epitaxial growth process. For example, the epitaxial layer may be formed by the epitaxial growth process (e.g., a molecular beam epitaxy (MBE), a pulsed laser deposition (PLD), a chemical vapor deposition (CVD) or an atomic layer deposition (ALD)). The substrate region 102 may include a frontside 102a (also referred to herein interchangeably as a top surface of the substrate region 102) and a backside 102b (also referred to herein interchangeably as a bottom surface of the substrate region 102) facing opposite directions. For example, the frontside 102a and the backside 102b may be extended along a horizontal direction DRh. The horizontal direction DRh may refer to a direction parallel to the frontside 102a and/or the backside 102b (e.g., parallel to the top surface of the substrate region 102 which may be the frontside 102a of the substrate region 102, parallel to the bottom surface of the substrate region 102 which may be the backside 102b of the substrate region 102, or any combination thereof) rather than a specific direction. For example, the horizontal direction DRh may be a first direction DR1, a second direction DR2, or a combination of the first direction DR1 and the second direction DR2. The backside 102b may be spaced apart from the frontside 102a along a vertical direction DRv. For example, the vertical direction DRv may be perpendicular to the horizontal direction DRh. The vertical direction DRv may refer to a direction perpendicular to the frontside 102a and/or the backside 102b (e.g., perpendicular to the top surface of the substrate region 102 which may be the frontside 102a of the substrate region 102, perpendicular to the bottom surface of the substrate region 102 which may be the backside 102b of the substrate region 102, or any combination thereof).

A floating diffusion pattern 104 may be provided on the substrate region 102. The floating diffusion pattern 104 may be protruded from the frontside 102a. The floating diffusion pattern 104 may be formed by implanting impurities into a semiconductor pattern that is the same or substantially the same as the substrate region 102. In some example embodiments, the floating diffusion pattern 104 may include the same or substantially the same material as the substrate region 102. In some example embodiments, the floating diffusion pattern 104 may include a material different from that of the substrate region 102. For example, the floating diffusion pattern 104 may include silicon (Si), germanium (Ge), or silicon-germanium (Si—Ge). The floating diffusion pattern 104 may have the second conductivity type. For example, the floating diffusion pattern 104 may be formed by implanting the second impurities into the semiconductor pattern provided on the substrate region 102 using a high-energy ion beam. The substrate region 102 and the floating diffusion pattern 104 may be formed as a single-layer structure (e.g., the substrate region 102 and the floating diffusion pattern 104 may be separate portions of a single, unitary piece of material). For example, the substrate region 102 and the floating diffusion pattern 104 may be connected to each other without an interface therebetween. In some example embodiments, the floating diffusion pattern 104 may be a region formed by etching an upper portion of the substrate region 102. In some example embodiments, the floating diffusion pattern 104 may be the epitaxial layer formed by the epitaxial growth process using the substrate region 102 as a seed layer.

A device isolation layer 110 may be provided adjacent (e.g., directly adjacent) to the frontside 102a of the substrate region 102. The device isolation layer 110 may define an active region. From a planar view, the device isolation layer 110 may surround the active region. The active region may be a region where a transfer gate electrode 200 and a floating diffusion region FD, which will be described later, are provided. For example, the device isolation layer 110 may be a shallow trench isolation (STI) layer. The device isolation layer 110 may be extended along (e.g., parallel to) the vertical direction DRv. In some example embodiments, and as shown in FIGS. 4A and 4B, the top surface of the device isolation layer 110 may be located at the same or substantially the same level as the frontside 102a and thus may be coplanar or substantially coplanar with the frontside 102a. A thickness of the device isolation layer 110 may be smaller than a thickness of a pixel isolation layer 120, which will be described later. The thickness of the device isolation layer 110 may be the size of the device isolation layer 110 along the vertical direction DRv. The device isolation layer 110 may include a silicon-based electrically insulating material. For example, the device isolation layer 110 may include at least one of silicon oxide (SiOₓ), silicon nitride (SiNₓ), or silicon oxynitride (SiOₓN_{y}).

A pixel isolation layer 120 may be provided on a lateral surface (e.g., sidewall) of the substrate region 102. For example, the pixel isolation layer 120 may be a deep trench isolation (DTI) layer. The pixel isolation layer 120 may be configured to optically and electrically separate adjacent pixel regions from each other. The pixel isolation layer 120 may be extended along the vertical direction DRv. For example, the top and bottom surfaces of the pixel isolation layer 120 may be located at substantially the same level as those of the frontside 102a and the backside 102b, respectively. The pixel isolation layer 120 may include a first pixel isolation layer 120a, a second pixel isolation layer 120b, and a capping layer 120c.

The first pixel isolation layer 120a may be disposed closer to the backside 102b than the capping layer 120c. The first pixel isolation layer 120a may have a refractive index lower than that of the substrate region 102. The first pixel isolation layer 120a may prevent or reduce the electrical crosstalk phenomenon that lowers the signal-to-noise ratio (SNR) by exchanging charge carriers between the adjacent pixel regions. For example, the first pixel isolation layer 120a may include an electrically conductive material (e.g., at least one of doped polysilicon, metal, metal silicide, metal nitride, and a metal-containing material), an electrically insulating material (e.g., at least one of silicon oxide (SiOₓ), silicon nitride (SiNₓ), or silicon oxynitride (SiOₓN_{y})), or a high-k dielectric material (e.g., a metal oxide containing at least one metal selected from the group consisting of hafnium (Hf), zirconium (Zr), aluminum (Al), tantalum (Ta), titanium (Ti), yttrium (Y), and lanthanum (La)).

The second pixel isolation layer 120b may be provided on sidewalls of the first pixel isolation layer 120a and the capping layer 120c. The second pixel isolation layer 120b may be provided between the first pixel isolation layer 120a and the substrate region 102. The second pixel isolation layer 120b may be configured to separate the first pixel isolation layer 120a from the substrate region 102. The second pixel isolation layer 120b may prevent, minimize, or reduce the optical crosstalk, which is detected not in the pixel into which light is incident, but in a pixel adjacent to it. In some example embodiments, the second pixel isolation layer 120b may be doped with a highly reflective material. For example, the highly reflective material may include boron (B). When the first pixel isolation layer 120a includes an electrically conductive material, the second pixel isolation layer 120b may include a negative fixed charge layer. The negative fixed charge layer may include a metal oxide containing at least one metal selected from a group consisting of, for example, hafnium (Hf), zirconium (Zr), aluminum (Al), tantalum (Ta), titanium (Ti), yttrium (Y), and lanthanum (La). As another example, the second pixel isolation layer 120b may include at least one of silicon oxide (SiOₓ), silicon nitride (SiNₓ), or silicon oxynitride (SiOₓN_{y}).

The capping layer 120c may be provided on the first pixel isolation layer 120a. The capping layer 120c may be disposed closer to the frontside 102a than the first pixel isolation layer 120a. The capping layer 120c and the first pixel isolation layer 120a may be arranged along the vertical direction DRv. The capping layer 120c may include an electrically insulating material. For example, the capping layer 120c may include a silicon-based electrically insulating material (e.g., at least one of silicon oxide (SiOₓ), silicon nitride (SiNₓ), or silicon oxynitride (SiOₓN_{y})) or a high-k dielectric material (e.g., hafnium oxide (HfOₓ), aluminum oxide (AlOₓ), or a combination thereof).

An impurity barrier region 130 may be provided within the substrate region 102 (e.g., between the frontside 102a and the backside 102b in the vertical direction DRv and between adjacent, opposing pixel isolation layers 120 that are at opposite sides of the substrate region 102 in the horizontal direction DRh). The impurity barrier region 130 may be located adjacent to the pixel isolation layer 120. The impurity barrier region 130 may have the first conductivity type. The impurity barrier region 130 may be configured to reduce the dark current caused by surface defects occurred on a surface of the substrate region 102 adjacent to the pixel isolation layer 120. For example, the surface defects in the substrate region 102 adjacent to the pixel isolation layer 120 may occur during an etching process of the substrate region 102 to form the pixel isolation layer 120.

A photoelectric conversion region CR may be provided within the substrate region 102 (e.g., between the frontside 102a and the backside 102b in the vertical direction DRv and between adjacent, opposing pixel isolation layers 120 that are at opposite sides of the substrate region 102 in the horizontal direction DRh). In some example embodiments, the photoelectric conversion region CR may include a photodiode including the first conductivity type region and a second conductivity type region. For example, the photoelectric conversion region CR may include a p-n photodiode. In some example embodiments, a p-type region of the photoelectric conversion region CR may be the substrate region 102, and a n-type region may be formed by implanting the second impurity into the substrate region 102. In some example embodiments, the p-type region may be formed by implanting the first impurity into the substrate region 102. In this case, a doping concentration of the p-type region may be higher than that of the substrate region 102. The p-type and the n-type regions may have a potential gradient by the p-n junction structure. It is an example that the photoelectric conversion region CR includes the pn photodiode. In some example embodiments, the photoelectric conversion region CR may include phototransistors, or pinned photodiodes.

When light is incident on the photoelectric conversion region CR, electron-hole pairs may be generated in the photoelectric conversion region CR. For example, the electron-hole pairs may be generated in a depletion region formed in a region adjacent to a p-n junction. The stronger the intensity of light incident on the photoelectric conversion region CR, the more electron-hole pairs may be generated. When a reverse bias is applied to the photoelectric conversion region CR, charge carriers (electrons or holes) may be accumulated in the photoelectric conversion region CR. The charge carriers accumulated in the photoelectric conversion region CR may be transferred to the floating diffusion region FD, which will be described later, along a channel formed by a voltage applied to the transfer gate electrode 200, which will be described later. The photoelectric conversion region CR may be spaced apart from the floating diffusion region FD.

The transfer gate electrode 200 may be provided on the substrate region 102. The transfer gate electrode 200 may include a buried region 200a and a capping region 200b. The buried region 200a may be buried in (e.g., within a volume space defined by outermost surfaces and/or boundaries of, etc.) the substrate region 102. The buried region 200a may be located between the frontside 102a and the backside 102b in the vertical direction DRv. The buried region 200a may be located between adjacent, opposing surfaces of one or more pixel isolation layers 120 at opposite sides of the substrate region 102 in the horizontal direction DRh. The buried region 200a may be extended along the vertical direction DRv. The width of the buried region 200a (e.g., in a horizontal direction DRh) may be decreased along the vertical direction DRv towards the backside 102b. For example, the width of the buried region 200a may be the size of the buried region 200a along the horizontal direction DRh.

The capping region 200b may be provided on the buried region 200a. The capping region 200b may be located at a higher level than the frontside 102a. The capping region 200b may at least partially overlap the floating diffusion pattern 104 along the horizontal direction DRh. In some example embodiments, the buried region 200a and the capping region 200b may be formed as a single-layer structure. For example, the buried region 200a and the capping region 200b may be connected to each other without an interface between them, such that the buried region 200a and the capping region 200b are separate portions of a single, unitary piece of material. As shown, the boundary between the buried region 200a and the capping region 200b may be defined to be a same level as the frontside 102a and thus may be coplanar with the frontside 102a. In some example embodiments, a thickness of the capping region 200b may be less than a thickness of the buried region 200a. The thickness of the capping region 200b may be the size of the capping region 200b along the vertical direction DRv. The thickness of the buried region 200a may be the size of the buried region 200a along the vertical direction DRv.

As described herein, a “level” or “vertical level” of an element may refer to a distance of the element from a reference location (e.g., the backside 102b of the substrate region 102) in the vertical direction DRv. When an element is described herein to be at a “higher level” than another element, the element may be further from the reference location (e.g., the backside 102b of the substrate region 102) in the vertical direction DRv than the other element. When an element is described herein to be at a “lower level” than another element, the element may be closer to the reference location (e.g., the backside 102b of the substrate region 102) in the vertical direction DRv than the other element.

The transfer gate electrode 200 may be referred to as a vertical transfer gate VTG. The transfer gate electrode 200 may include an electrically conductive material. For example, the transfer gate electrode 200 may include polysilicon (e.g., doped polysilicon), metal silicide, or metal (e.g., copper (Cu), aluminum (Al), molybdenum (Mo), platinum (Pt), titanium (Ti), tantalum (Ta), tungsten (W), or a combination thereof).

A transfer gate insulating layer 210 may be extended (e.g., may extend) along (e.g., may conformally cover) a surface of the transfer gate electrode 200, including for example a lateral surface 200s of the transfer gate electrode 200. A portion of the transfer gate insulating layer 210 may be provided between the transfer gate electrode 200 and the substrate region 102. Another portion of the transfer gate insulating layer 210 may be provided between the transfer gate electrode 200 and the device isolation layer 110. The transfer gate insulating layer 210 may be configured to cover the sidewall (e.g., later surface 200s) and the bottom surfaces of the transfer gate electrode 200. The transfer gate insulating layer 210 may contact the floating diffusion region FD (e.g., contact at least a portion of a sidewall FDs of the floating diffusion region FD as shown in FIG. 4A). The transfer gate insulating layer 210 may be configured to electrically separate the transfer gate electrode 200 and the substrate region 102. For example, the transfer gate insulating layer 210 may be a silicon-based electrically insulating material (e.g., at least one of silicon oxide (SiOₓ), silicon nitride (SiNₓ), or silicon oxynitride (SiOₓN_{y})) or a high-k dielectric material (e.g., a metal oxide containing at least one metal selected from the group consisting of hafnium (Hf), zirconium (Zr), aluminum (Al), tantalum (Ta), titanium (Ti), yttrium (Y), and lanthanum (La)).

A first transfer gate spacer 220 may be provided on the opposite side of the floating diffusion pattern 104 with respect to the transfer gate electrode 200, such that the transfer gate electrode 200 is between the first transfer gate spacer 220 and the floating diffusion pattern 104 in the horizontal direction DRh. The first transfer gate spacer 220 may be provided on a lateral surface (e.g., sidewall) of the transfer gate electrode 200 located opposite to the floating diffusion pattern 104. For example, the first transfer gate spacer 220 may be provided on a lateral surface of the capping region 200b located opposite the floating diffusion pattern 104. The first transfer gate spacer 220 may include a first spacer cap 220a and a first spacer liner 220b. The first spacer cap 220a may be located at a higher level than the frontside 102a. The first spacer cap 220a may overlap the capping region 200b and the floating diffusion pattern 104 along the direction parallel to the frontside 102a. For example, the first spacer cap 220a may overlap the capping region 200b and the floating diffusion pattern 104 along the horizontal direction DRh. The first spacer cap 220a may include an electrically insulating material. For example, the first spacer cap 220a may include silicon nitride (SiNₓ), silicon carbide nitride (SiCₓN_{y}), silicon oxynitride (SiOₓN_{y}), or a combination thereof.

The first spacer liner 220b may be provided on a lateral and the bottom surfaces of the first spacer cap 220a. The first spacer liner 220b may be extended along the lateral and the bottom surfaces of the first spacer cap 220a. For example, the first spacer liner 220b may conformally cover the lateral and the bottom surfaces of the first spacer cap 220a. For example, the first spacer cap 220a and the transfer gate electrode 200 may be spaced apart from each other by the first spacer liner 220b. The first spacer liner 220b may include an electrically insulating material different from that of the first spacer cap 220a. For example, the first spacer liner 220b may include silicon oxide (SiOₓ).

A second transfer gate spacer 222 may be provided between the transfer gate electrode 200 and the floating diffusion pattern 104 (e.g., between the transfer gate electrode 200 and the floating diffusion pattern 104 in the horizontal direction DRh). The second transfer gate spacer 222 may be provided on the lateral surface of the transfer gate electrode 200 adjacent to the floating diffusion pattern 104. For example, the second transfer gate spacer 222 may be provided on a lateral surface of the buried region 200a and the lateral surface of the capping region 200b adjacent to the floating diffusion pattern 104. The second transfer gate spacer 222 may include a second spacer cap 222a and a second spacer liner 222b. As shown, the second transfer gate spacer 222 may contact at least a portion of the floating diffusion region FD, including for example contacting at least a portion of a sidewall FDs of the floating diffusion region FD extending to a top surface of the floating diffusion region FDa (which may be the same as the frontside 102a of the substrate region 102).

The second spacer cap 222a may be extended from a region at a higher level than the frontside 102a to a region at a lower level than the frontside 102a. A portion of the second spacer cap 222a may overlap the capping region 200b and the floating diffusion pattern 104 along the horizontal direction DRh. Another portion of the second spacer cap 222a may overlap the buried region 200a along the direction parallel to the frontside 102a. The second spacer cap 222a may include an electrically insulating material. For example, the second spacer cap 222a may include silicon nitride (SiNₓ), silicon carbide nitride (SiCₓN_{y}), silicon oxynitride (SiOₓN_{y}), or a combination thereof.

The second spacer liner 222b may be provided on the lateral and the bottom surfaces of the second spacer cap 222a. The second spacer liner 222b may be extended along the lateral and the bottom surfaces of the second spacer cap 222a. For example, the second spacer liner 222b may conformally cover the lateral and the bottom surfaces of the second spacer cap 222a. For example, the second spacer cap 222a and the transfer gate electrode 200 may be spaced apart from each other by the second spacer liner 222b. The second spacer liner 222b may include an electrically insulating material. For example, the second spacer liner 222b may include silicon oxide (SiOₓ).

The floating diffusion region FD may be provided within the substrate region 102. The floating diffusion region FD may have the second conductivity type. For example, the floating diffusion region FD may be formed by implanting the second impurity into the substrate region 102 using a low-energy ion beam. The floating diffusion region FD may have a gradient of doping concentration. For example, the floating diffusion region FD may have a larger doping concentration as it approaches the floating diffusion pattern 104. For example, the doping concentration in the floating diffusion region FD may increase with increasing proximity to (e.g., reduced distance from) the floating diffusion pattern 104 in the vertical direction DRv. For example, the doping concentration in the floating diffusion region FD may be proportional to proximity to the floating diffusion pattern 104 in the vertical direction DRv. For example, the gradient of doping concentration in the floating diffusion region FD may be formed when the second impurity in the floating diffusion pattern 104 diffuses into the substrate region 102 during a heat treatment process. For example, the heat treatment process may be performed to activate the floating diffusion region FD and the floating diffusion pattern 104 after an ion implantation process.

The floating diffusion region FD and floating diffusion pattern 104 may form a gradually changing potential profile. The floating diffusion region FD and the floating diffusion pattern 104 may be provided to prevent the charge carriers generated in the photoelectric conversion region CR) from being transferred in a non-ideal form along the floating diffusion region FD and the floating diffusion pattern 104.

The floating diffusion region FD may at least partially overlap the buried region 200a along the horizontal direction DRh. The floating diffusion pattern 104 and the floating diffusion region FD may be arranged along the vertical direction DRv. The floating diffusion pattern 104 and the floating diffusion region FD may at least partially overlap each other along the vertical direction DRv. The floating diffusion pattern 104 and the floating diffusion region FD may be in contact with each other. Hereinafter, a structure in which the floating diffusion pattern 104 and the floating diffusion region FD are arranged along the vertical direction DRv may be referred to as a vertical charge transfer structure. The floating diffusion pattern 104 and the floating diffusion region FD may function as the drain of the transfer transistor (TX in FIG. 3) and the source of the reset transistor (RX in FIG. 3). The floating diffusion pattern 104 and the floating diffusion region FD may be electrically connected to a source follower gate of a source follower transistor (DX in FIG. 3). The source follower transistor (DX in FIG. 3) may be connected to a select transistor (SX in FIG. 3).

Referring to FIG. 4B, a pixel transistor 1200 may be provided. The pixel transistor 1200 may include a pixel gate electrode 1210, a pixel gate spacer 1220, a pixel gate capping layer 1230, and a pair of pixel sources/drains 1300. For example, the pixel transistor 1200 may be the source follower transistor. The pixel gate electrode 1210 may be provided on the substrate region 102. The pixel gate electrode 1210 may include an electrically conductive material. For example, the pixel gate electrode 1210 may include polysilicon (e.g., doped polysilicon), metal silicide, or metal (e.g., copper (Cu), aluminum (Al), molybdenum (Mo), platinum (Pt), titanium (Ti), tantalum (Ta), tungsten (W), or a combination thereof).

The pixel gate spacer 1220 may be provided on the lateral surface of the pixel gate electrode 1210. The pixel gate spacer 1220 may include an electrically insulating material. For example, the pixel gate spacer 1220 may include at least one of silicon oxide (SiOₓ), silicon nitride (SiNₓ), or silicon oxynitride (SiOₓN_{y}).

The pixel gate capping layer 1230 may cover the pixel gate electrode 1210 and the pixel gate spacer 1220. The pixel gate capping layer 1230 may include an electrically insulating material. For example, the pixel gate capping layer 1230 may include a silicon nitride (SiNₓ) layer.

The pair of pixel source/drains 1300 may be provided within the substrate region 102, for example such that, as shown in FIG. 4B, the pair of pixel sources/drains 1300 include a first pixel source/drain on one lateral surface of the pixel gate electrode 1210 and a second pixel source/drain on another (e.g., opposite) lateral surface of the pixel gate electrode, and where the first pixel source/drain and the second pixel source/drain are both within the substrate region 102. For example, the pair of pixel source/drains 1300 may be regions formed by implanting impurities into the substrate region 102. For example, the pair of pixel source/drains 1300 may have the second conductivity type. The pair of pixel sources/drains 1300 may be provided in a region adjacent to the frontside 102a of the substrate region 102. The pair of pixel sources/drains 1300 may be spaced apart from each other with the pixel gate electrode 1210 interposed therebetween.

The area occupied by components for one pixel (e.g., the area in a plane extending in horizontal directions DRh) may be defined as the fill factor. The fill factor may be the ratio of the area occupied by the pixel gate electrode 1210 to the area of the pixel region. The area of the pixel gate electrode 1210 may be increased by the vertical charge transfer structure. As the area of the pixel gate electrode 1210 is increased, the fill factor may be improved, thereby enabling improvement of the sensitivity (and thus performance), improved photoelectric conversion efficiency, etc. of the image sensor PA1. Furthermore, random noise, random telegraph noise, and linearity of the voltage-current graph may be improved (e.g., noise may be reduced or minimized), and thus the image capturing/generating performance of the image sensor 1000 may be improved, by increasing the amount of current in the pixel transistors.

A capacitance may be defined between the floating diffusion region FD and the substrate region 102. The area of an interface between the floating diffusion region FD and the substrate region 102 may be one of the factors that determine the capacitance. The area of the interface between the floating diffusion region FD and the substrate region 102 may be reduced by the vertical charge transfer structure. Accordingly, the capacitance is reduced, and conversion gain and random noise may be improved, and thus the image capturing/generating performance of the image sensor PA1 may be improved.

The floating diffusion region FD may be spaced apart from the photoelectric conversion region CR with the substrate region 102 interposed therebetween. The floating diffusion region FD may receive and accumulate the charge carriers provided from the photoelectric conversion region CR. The vertical charge transfer structure may provide (e.g., at least partially define, at least partially form, etc.) a first charge transfer path P1. The first charge transfer path PI may be a path in which the charge carriers sequentially follow the substrate region 102 adjacent to the transfer gate electrodes 200, the floating diffusion region FD, and the floating diffusion pattern 104. The first charge transfer path P1 may be spaced apart from the frontside 102a. The first charge transfer path P1 may extend at least partially vertically in relation to the frontside (e.g., extend at an angle between about 45 degrees and about 90 degrees in relation to the frontside 102a, extend at an angle between about 60 degrees and about 90 degrees in relation to the frontside 102a, extend at an angle between about 75 degrees and about 90 degrees in relation to the frontside 102a, extend at an angle between about 85 degrees and about 90 degrees in relation to the frontside 102a, extend perpendicular or substantially perpendicular to the frontside 102a, or any combination thereof) as the first charge transfer path Pl transfers charge carriers from the photoelectric conversion region CR to the floating diffusion pattern 104. For example, the first charge transfer path P1 may be defined by the image sensor PA1 to extend perpendicular or substantially perpendicular to the frontside 102a at the frontside 102a (e.g., extend perpendicular or substantially perpendicular to the frontside 102a at the interface between the floating diffusion region FD and the floating diffusion pattern 104). Accordingly, when the charge carriers are transferred, there may be little or no effect of charge trapping by surface defects of the frontside 102a. That is, the first charge transfer path P1 may be a path in which the charge carriers are not trapped in charge traps. The vertical charge transfer structure may be provided to prevent the charge carriers from being trapped in charge traps, or reduce or minimize such trapping, and thus the image capturing/generating performance of the image sensor PA1 may be improved. The image sensor PA1 may provide improved fixed-pattern noise and linearity of the voltage-current graph by the charge carriers transferred onto the first charge transfer path P1, and thus the image capturing/generating performance of the image sensor PA1 may be improved.

A wire insulating layer 300 may be provided on the substrate region 102 to cover the transfer gate electrode 200 and the floating diffusion pattern 104. The wire insulating layer 300 may include a first wire insulating layer 302 and a second wire insulating layer 304. The first and the second wire insulating layers 302 and 304 may be sequentially stacked on the frontside 102a. As an example, the wire insulating layer 300 may include two insulating layers (i.e. the first and the second wire insulating layers 302 and 304). In some example embodiments of the inventive concepts, the wire insulating layer 300 may include three or more insulating layers. The first and the second wire insulating layers 302 and 304 may include an electrically insulating material. The first and the second wire insulating layers 302 and 304 may include, for example, silicon oxide (SiOₓ), silicon nitride (SiNₓ), silicon oxynitride (SiOₓN_{y}), germanium oxide (GeOₓ), germanium nitride (GeNₓ), germanium oxynitride (GeOₓN_{y}), or a combination thereof.

Wires 310 may be provided within the wire insulating layer 300. The wires 310 may include a horizontal wire 310a and a vertical wire 310b. The horizontal wire 310a may be extended along the direction parallel to the frontside 102a. For example, the direction parallel to the frontside 102a may be the horizontal direction DRh, the vertical direction DRv, or a combination of the horizontal direction DRh and the vertical direction DRv. The vertical wire 310b may be extended along the vertical direction DRv. The shown wires 310 are examples. The shape and the number of wires 310 may be appropriately selected as needed. The wires 310 may output electrical signals generated in the photoelectric conversion region CR to the outside. For example, the wires 310 may be provided between the floating diffusion pattern 104 and other electrical components to provide an electrical connection between the floating diffusion pattern 104 and other electrical components. The wires 310 may include an electrically conductive material (e.g., metal). For example, the wires 310 may include at least one of titanium (Ti), tungsten (W), tungsten nitride (WN), tantalum nitride (TaN), titanium nitride (TiN), ruthenium (Ru), niobium nitride (NbN), molybdenum (Mo), cobalt (Co), copper (Cu), aluminum (Al), silver (Ag), or gold (Au). The wires 310 may be electrically connected to at least one of the transfer gate, the source follower gate, the reset gate, or the selection gate. For example, the wires 310 may be configured to apply the power supply voltage VDD to the drain of the reset transistor RX or the drain of the source follower transistor DX.

A bottom insulating layer 400 may be provided on the backside 102b of the substrate region 102. The bottom insulating layer 400 may be configured to protect a lower portion of the substrate region 102. The bottom insulating layer 400 may include an electrically insulating material. For example, the bottom insulating layer 400 may include silicon oxide (SiOₓ), silicon nitride (SiNₓ), silicon oxynitride (SiOₓN_{y}), germanium oxide (GeOₓ), germanium nitride (GeNₓ), germanium oxynitride (GeOₓN_{y}), or a combination thereof. In some example embodiments, the bottom insulating layer 400 may be configured to reduce, minimize, or substantially prevent incident light from being reflected off the backside 102b. For example, the bottom insulating layer 400 may include tantalum (Ta) or tantalum nitride (TaN). The bottom insulating layer 400 may have a single-layer structure or a multi-layer structure.

Grid 410 may be provided on the bottom insulating layer 400. The grid 410 may surround a color filter 420, which will be described later. The grid 410 may be configured to optically separate the color filters 420 that are immediately adjacent to each other. From a planar view, the grid 410 may have a shape corresponding to the pixel isolation layer 120. For example, the grid 410 may overlap the pixel isolation layer 120 along the vertical direction DRv. The grid 410 may include a first grid 410a and a second grid 410b. The first grid 410a and the second grid 410b may be sequentially arranged along the vertical direction DRv. The first grid 410a may have a lower refractive-index than the color filter 420. In some example embodiments, the first grid 410a may include a low-refractive-index material with electrically insulating properties. The low-refractive-index material may increase the amount of light focused into the photoelectric conversion region CR. The first grid 410a may be configured to reduce optical crosstalk between the adjacent pixel regions, thereby reducing signal-to-noise ratio (SNR). For example, the low-refractive-index material may include a polymer containing nanoparticles (e.g., silica). In some example embodiments, the first grid 410a may include an organic material. The second grid 410b may be provided between the first grid 410a and the bottom insulating layer 400. In some example embodiments, the second grid 410b may include a different material with the first grid 410a. The second grid 410b may include an electrically conductive material (e.g., metal and metal nitride). For example, the second grid 410b may include tungsten (W), tantalum (Ta), titanium (Ti), titanium nitride (TiN), or a combination thereof. It is an example that the grid 410 is composed of the first and the second grids 410ₐand 410b. In some example embodiments, the grid 410 may have a single-layer structure or a multi-layer structure of three or more layers.

The color filter 420 may be provided on the bottom insulating layer 400. The color filter 420 may be configured to transmit light of a required wavelength region. In some example embodiments, the color filter 420 may transmit (e.g., selectively transmit) red light, green light, or blue light. In some example embodiments, the color filters 420 may transmit (e.g., selectively transmit) cyan light, magenta light, and yellow light. The color filters 420 may be formed by, for example, at least one of a dyeing method, a pigment dispersion method, an electrodeposition method, or a printing method. Incident light that has passed through the color filter 420 may be incident on the substrate region 102 corresponding to the color filter 420. In some example embodiments, from a planar view, the shape of the color filter 420 may be substantially the same as the shape of the substrate region 102. When a pixel array including a plurality of pixels is provided, the pixel array may include a plurality of the color filters 420. The color filters 420 may be arranged along the direction parallel to the backside 102b on the bottom insulating layer 400. The color filters 420 may be configured to transmit light of different wavelength regions in relation to each other.

A protective layer 430 may be provided between the bottom insulating layer 400 and the color filter 420 and between the grid 410 and the color filter 420. For example, the protective layer 430 may be extended conformally along surfaces of the grid 410 and the bottom insulating layer 400. The protective layer 430 may be configured to protect other components from the external environment. The protective layer 430 may include a high-k dielectric material (e.g., aluminum oxide (A1Oₓ) or hafnium oxide (HfOₓ)).

A microlens 440 may be provided on the color filter 420. A planarization layer (not shown) may be further provided between the microlens 440 and the color filter 420. The microlens 440 may be configured to focus incident light and provide it to the substrate region 102. The microlens 440 may have a convex shape along the vertical direction DRv. The microlens 440 may overlap the photoelectric conversion region CR along the vertical direction DRv. The microlens 440 may include at least one of silicon oxide (SiOₓ), silicon nitride (SiNₓ), or silicon oxynitride (SiOₓN_{y}).

The image sensor PA1 may be divided into a device layer, a wiring layer, and a lens layer. The wiring layer may include the wire insulating layer 300 and the wires 310. The lens layer may include the bottom insulating layer 400, the grid 410, the color filter 420, the protective layer 430, and the microlens 440. Except for the wiring layer and the lens layer, the remaining components may be included in a device layer. As an example, the wiring layer and the lens layer may be spaced apart from each other with the device layer (e.g., including the substrate region 102, the floating diffusion region FD, the floating diffusion pattern 104, the transfer gate electrode 200, and at least one of the first and/or second transfer gate spacers 220 and/or 222) interposed therebetween. For example, the image sensor PA1 including the wiring layer and the lens layer spaced apart from each other with the device layer in between may be driven in a backside illumination method. In some example embodiments of the inventive concepts, the lens layer and the device layer may be spaced apart from each other with the wiring layer interposed therebetween. For example, an image sensor including the lens layer and the device layer spaced apart from each other with the wiring layer in between may be driven in a front illumination method.

According to some example embodiments of the present inventive concepts, gate-induced leakage current may be reduced, minimized, or prevented based on the floating diffusion pattern 104 being provided on the substrate region 102. Accordingly, the image sensor PA1 with an improved fill factor may be provided and thus and thus the image capturing/generating performance of the image sensor PA1, the photoelectric conversion efficiency, etc. of the image sensor PA1 may be improved. Furthermore, since the first charge transfer path Pl of some example embodiments of the present inventive concepts is spaced apart from the frontside 102a, the influence of charge traps may be reduced, minimized, or prevented. Accordingly, the image sensor PA1 with improved charge trapping characteristics, and thus having improved functionality (e.g., improved image capturing/generating performance, improved photoelectric conversion efficiency, etc.), may be provided.

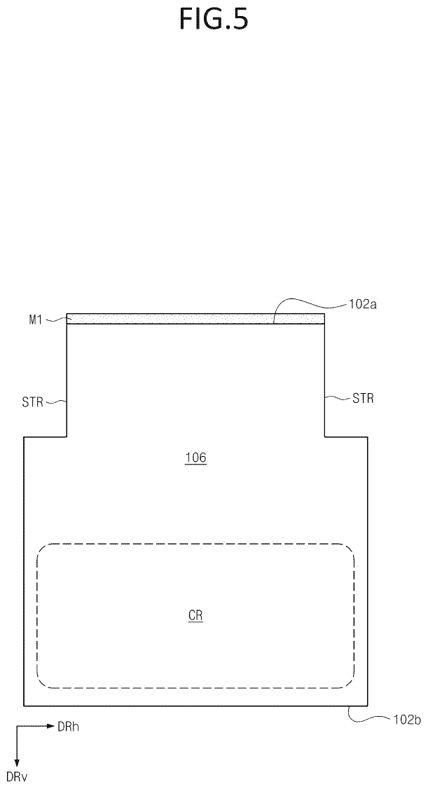

FIGS. 5, 6, 7, 8, 9, 10, 11, 12, and 13 are lines are cross-sectional views for explaining a method of manufacturing an image sensor according to some example embodiments. For brevity of explanation, features that are the same or substantially the same as that described with reference to FIGS. 4A and 4B may not be described.

Referring to FIG. 5, a semiconductor substrate may be prepared. The semiconductor substrate may have a first conductivity type. The first conductivity type may be, for example, p-type. Photoelectric conversion regions CR may be formed in a lower portion of the semiconductor substrate. In some example embodiments, the photoelectric conversion region CR may include a p-n photodiode. For example, the p-n photodiode may be formed by an ion implantation process. The ion implantation process may be, for example, a process of accelerating an ionized source material and implanting it into the semiconductor substrate. The source material may be ionized by plasma. The source material that allows the semiconductor substrate to be p-type may include a group 3 element (e.g., boron (B), aluminum (Al), gallium (Ga), or indium (In)). The source material that causes the semiconductor substrate to be n-type may include a group 5 element (e.g., phosphorus (P), arsenic (As), or antimony (Sb)), a group 6 element, or a group 7 element.

The semiconductor substrate may be etched to form a device isolation trench STR. The device isolation trench STR may be formed by a dry etching process or a wet etching process using a first mask pattern M1 provided on the semiconductor substrate (e.g., on the frontside 102a). For example, the dry etching process may be performed using plasma. For example, the wet etching process may be performed using a chemical solution (e.g., nitric acid (HNO₃), hydrofluoric acid (HF), or a combination thereof). The device isolation trench STR may be configured to extend along the vertical direction DRv. The etched semiconductor substrate may be referred to as a first preliminary substrate region 106.

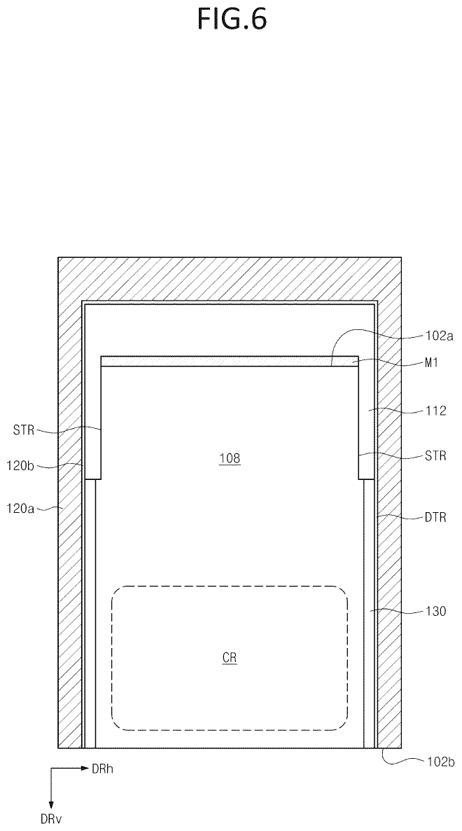

Referring to FIG. 6, a first preliminary device isolation layer 112 may be formed on the first preliminary substrate region 106 and the first mask pattern M1. The first preliminary device isolation layer 112 may be formed to fill the device isolation trench STR. The top surface of the first preliminary device isolation layer 112 may be located at a substantially higher level than the top surface of the first preliminary substrate region 106 and the top surface of the first mask pattern M1. Forming the first preliminary device isolation layer 112 may include depositing an electrically insulating material on the first preliminary substrate region 106 and the first mask pattern M1.

The first preliminary substrate region 106 may be etched to form a pixel isolation trench DTR. For example, etching the first preliminary substrate regions 106 may include the dry etching process or the wet etching process using a mask pattern (not shown) provided on the first preliminary device isolation layer 112. The pixel isolation trench DTR may be configured to extend along the vertical direction DRv. For example, the pixel isolation trench DTR may be extended from the top to the bottom of the first preliminary substrate region 106. The etched first preliminary substrate region 106 may be referred to as a second preliminary substrate region 108. For example, the first mask pattern M1 is shown remaining even after an etching process for the first preliminary substrate region 106. In some example embodiments, the first mask pattern M1 may be removed during the etching process for the first preliminary substrate region 106 or after the etching process is completed.

An impurity barrier region 130 may be formed within a sidewall of the second preliminary substrate region 108. The impurity barrier region 130 may be formed by implanting a first impurity into the sidewall of the second preliminary substrate region 108. The first impurity may include, for example, the group 3 element (e.g., boron (B), aluminum (Al), gallium (Ga), or indium (In)). In some example embodiments, the impurity barrier region 130 may be formed by the ion implantation process. In some example embodiments, forming the impurity barrier region 130 may include removing an impurity doped layer (not shown) after diffusing the first impurity in the impurity doping layer (not shown) formed on the sidewall of the second preliminary substrate region 108 into the sidewall of the second preliminary substrate region 108.

The second preliminary pixel isolation layer 122b may be formed on the pixel isolation trench DTR and the first preliminary device isolation layer 112. Forming the second preliminary pixel isolation layer 122b may include depositing a high-k dielectric material (e.g., a metal oxide containing at least one metal selected from the group consisting of hafnium (Hf), zirconium (Zr), aluminum (Al), tantalum (Ta), titanium (Ti), yttrium (Y), and lanthanum (La)), or an electrically insulating material (e.g., at least one of silicon oxide (SiOₓ), silicon nitride (SiNₓ), or silicon oxynitride (SiOₓN_{y}) on the sidewall of the second preliminary substrate region 108 and the top surface of the first preliminary device isolation layer 112.

A first preliminary pixel isolation layer 122a may be formed on the second preliminary pixel isolation layer 122b. The first preliminary pixel isolation layer 122a and the second preliminary pixel isolation layer 122b may include materials different from each other (e.g., may have different total material compositions). For example, forming the first preliminary pixel isolation layer 122a may include forming an electrically conductive material (e.g., at least one of doped polysilicon, metal, metal nitride, silicide, or a metal-containing material), an electrically insulating material (e.g., at least one of silicon oxide (SiOₓ), silicon nitride (SiNₓ), or silicon oxynitride (SiOₓN_{y})), or a high-k dielectric material (e.g., a metal oxide comprising at least one metal selected from the group consisting of hafnium (Hf), zirconium (Zr), aluminum (Al), tantalum (Ta), titanium (Ti), yttrium (Y), and lanthanum (La)) on the second preliminary pixel isolation layer 122b. In some example embodiments, the first preliminary pixel isolation layer 122a may be formed to completely fill the pixel isolation trenches DTR.

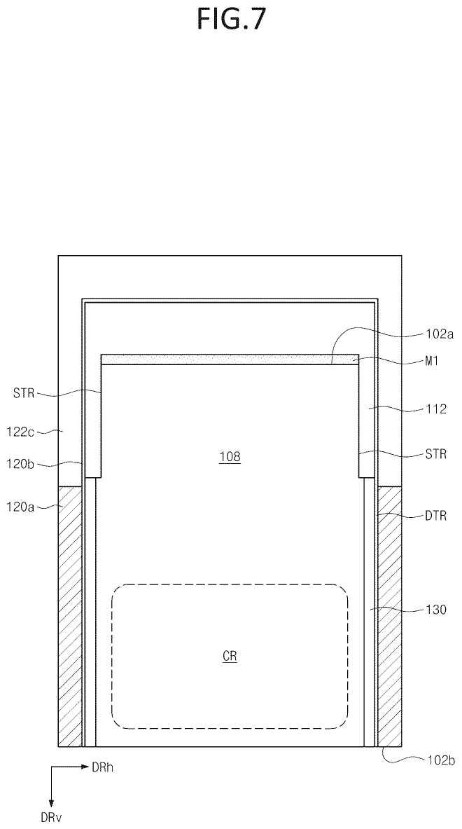

Referring to FIG. 7, an upper portion of the first preliminary pixel isolation layer 122a may be etched to form a first pixel isolation layer 120a. Etching the upper portion of the first preliminary pixel isolation layer 122a may include, for example, the dry etching process or the wet etching process. The top surface of the first pixel isolation layer 120a may be located at a substantially lower level than the bottom surface of the device isolation trenches STR. A preliminary capping layer 122c may be formed on the first pixel isolation layer 120a. The preliminary capping layer 122c and the first pixel isolation layer 120a may include materials different from each other. For example, forming the preliminary capping layer 122c may include depositing a silicon-based electrically insulating material (e.g., at least one of silicon oxide (SiOₓ), silicon nitride (SiNₓ), or silicon oxynitride (SiOₓN_{y})) or a high-k dielectric material (e.g., hafnium oxide (HfOₓ), aluminum oxide (AlOₓ), or a combination thereof) on the first pixel isolation layer 120a.

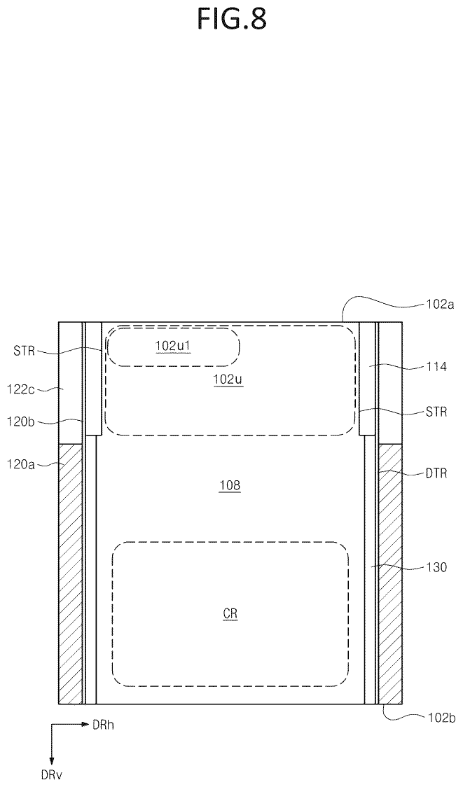

Referring to FIG. 8, a planarization process is performed on the first preliminary device isolation layer 112, the second preliminary pixel isolation layer 122b, and the preliminary capping layer 122c, thereby forming a second preliminary device isolation layer 114, the second pixel isolation layer 120b, and the capping layer 120c. The planarization process may be a process of etching surfaces, for example, chemically, mechanically, or a combination thereof. The planarization process may be performed until the second preliminary substrate region 108 is exposed. The first mask pattern M1 may be removed during the planarization process. The first mask pattern M1 may reduce, minimize, or prevent damage to a surface of the second preliminary substrate region 108 (e.g., frontside 102ₐ).

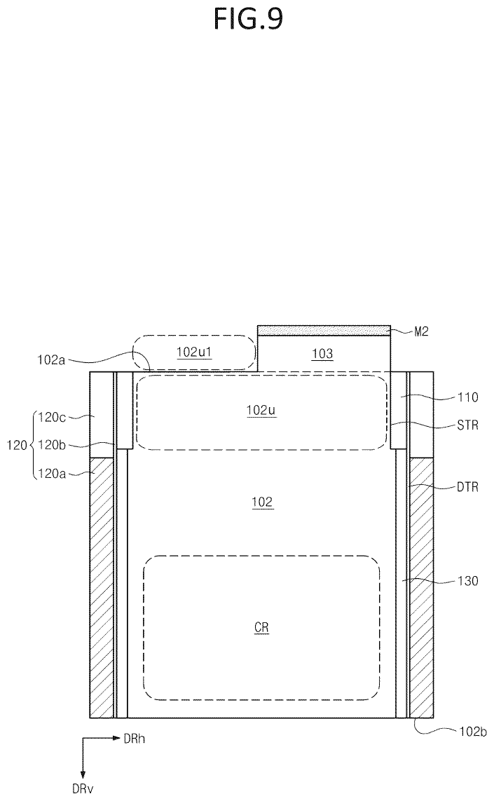

Referring to FIG. 9 and further referring to FIG. 8, the second preliminary substrate region 108 (e.g., an upper portion 102u of the second preliminary substrate region 108), the second preliminary device isolation layer 114, the second preliminary pixel isolation layer 122b, and the preliminary capping layer 122c may be etched (e.g., etching the upper portion 102u to remove at least a first upper portion 102ul of the second preliminary substrate region 108) to form the substrate region 102 and a preliminary floating diffusion pattern 103. As shown, the upper portion 102u of the substrate region 102 may be defined as a portion of the substrate region 102 extending in the vertical direction DRv from the frontside 102a to a level of a bottom surface of the device isolation layer 110. The etching process of the second preliminary substrate region (108 in FIG. 8), the second preliminary device isolation layer 114, the second preliminary pixel isolation layer 122b, and the preliminary capping layer 122c may include the dry etching process or the wet etching process using a second mask pattern (M2) provided on the second preliminary substrate region (108 in FIG. 8). The second mask pattern M2 may be removed during the etching process or after the etching process. The substrate region 102 may include a frontside 102a and a backside 102b facing opposite directions. Etching the second preliminary substrate region 108 may be an example of a method of forming the preliminary floating diffusion pattern 103.

in some example embodiments of the inventive concepts, a selective epitaxial growth process (e.g., a molecular beam epitaxy (MBE), a pulsed laser deposition (PLD), a chemical vapor deposition, a chemical vapor deposition (CVD), or an atomic layer deposition (ALD)) may be performed to form the preliminary floating diffusion pattern 103 (e.g., such that a first upper portion 102ul of the second preliminary substrate region 108 is not removed via etching). In some example embodiments, the substrate region 102 and the preliminary floating diffusion pattern 103 may include the same material. When the substrate region 102 and the preliminary floating diffusion pattern 103 include the same material, the substrate region 102 and the preliminary floating diffusion pattern 103 may form a single-layer structure. For example, the substrate region 102 and the preliminary floating diffusion pattern 103 may be connected to each other without an interface therebetween. For example, the substrate region 102 and the preliminary floating diffusion pattern 103 may be separate portions of a single, unitary piece of material. In some example embodiments, the substrate region 102 and the preliminary floating diffusion pattern 103 may include materials different from each other (e.g., may have different total material compositions).

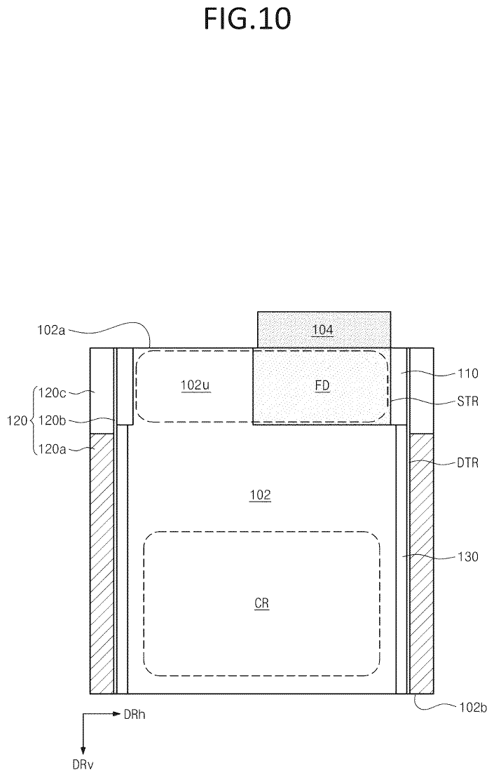

Referring to FIG. 10, a floating diffusion region FD may be formed within the substrate region 102 (e.g., at the upper portion 102u of the substrate region 102). In some example embodiments, the floating diffusion region FD may be formed by the ion implantation process. For example, the floating diffusion region FD may be formed by the process of accelerating ionized source material and implanting it into the substrate regions 102. For example, the source material may include the group 5 element (e.g., phosphorus (P), arsenic (As), or antimony (Sb)), the group 6 element, or the group 7 element.

A floating diffusion pattern 104 may be formed. In some example embodiments, the floating diffusion pattern 104 may be formed by the ion implantation process. For example, the floating diffusion pattern 104 may be formed by the process of accelerating ionized source material and implanting it into the preliminary floating diffusion pattern 103. For example, the source material may include the group 5 element (e.g., phosphorus (P), arsenic (As), or antimony (Sb)), a group 6 element, or a group 7 element.

A heat treatment process may be performed to activate the floating diffusion region FD and the floating diffusion pattern 104. During the heat treatment process, second impurities in the floating diffusion pattern 104 may diffuse into the substrate region 102. Accordingly, the floating diffusion region FD may have a gradient of doping concentration. For example, the floating diffusion region FD may have a larger doping concentration as it approaches the floating diffusion pattern 104. For example, the floating diffusion region FD may have a doping concentration that increases with increasing proximity to (e.g., reduced distance from) the floating diffusion pattern 104 in the vertical direction DRv. The heat treatment process may be performed using, for example, an electric furnace. The heat treatment process may be performed prior to, concurrently with, and/or subsequently to any of the operations of the method as shown in FIGS. 10, 11, 12, and/or 13, although example embodiments are not limited thereto. In some example embodiments, the heat treating may be performed subsequently to forming the floating diffusion pattern 104 and prior to forming the transfer gate electrode 200, first and/or second transfer gate spacers 220 and/or 222, or the like.

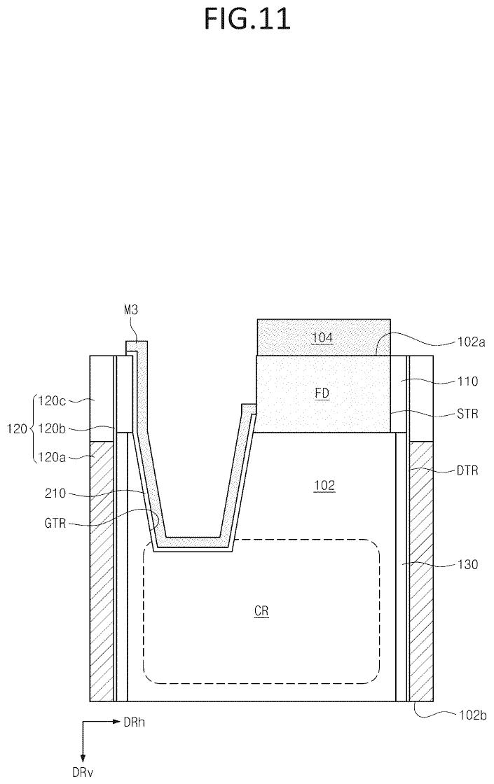

Referring to FIG. 11, the substrate region 102 may be etched to form a transfer gate trench GTR. Etching the substrate region 102 may include the dry etching process or the wet etching process using a mask pattern (not shown) provided on the substrate region 102. The mask pattern (not shown) may be removed during the etching process or after the etching process.

A preliminary transfer gate insulating layer (not shown) may be formed on the lateral surface of the transfer gate trench GTR. For example, the preliminary transfer gate insulating layer (not shown) may be conformally formed along the lateral surface of the transfer gate trench GTR. Forming the preliminary transfer gate insulating layer (not shown) may include depositing a silicon-based electrically insulating material (e.g., at least one of silicon oxide (SiOₓ), silicon nitride (SiNₓ), or silicon oxynitride (SiOₓN_{y})) or a high-k dielectric material (e.g., a metal oxide containing at least one metal selected from the group consisting of hafnium (Hf), zirconium (Zr), aluminum (Al), tantalum (Ta), titanium (Ti), yttrium (Y), and lanthanum (La)) on the transfer gate trench GTR.

The preliminary transfer gate insulating layer (not shown) may be etched to form a transfer gate insulating layer 210. Etching the preliminary transfer gate insulating layer (not shown) may include the dry etching process or the wet etching process using a third mask pattern M3 formed on the preliminary transfer gate insulating layer (not shown). The third mask pattern M3 may be removed during the etching process or after the etching process. The transfer gate insulating layer 210 may be formed in the transfer gate trench GTR.

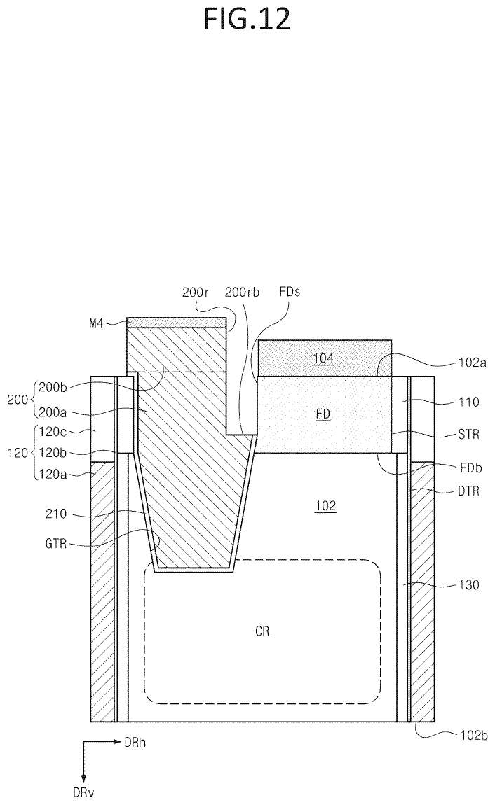

Referring to FIG. 12, a transfer gate electrode 200 may be formed. Forming the transfer gate electrode 200 may include forming a preliminary transfer gate electrode (not shown) filling the transfer gate trench GTR and etching the preliminary transfer gate electrode (not shown) to the desired shape. Forming the preliminary transfer gate electrode (not shown) may include polysilicon (e.g., doped polysilicon), silicide, or metal (e.g., copper (Cu), aluminum (Al), molybdenum (Mo), platinum (Pt), titanium (Ti), tantalum (Ta), tungsten (W), or a combination thereof) to fill the transfer gate trench GTR on substrate region 102. The preliminary transfer gate electrode (not shown) may be formed to a higher level (e.g., greater distance from the backside 102b in the vertical direction DRv) than the frontside 102a of the substrate region 102. Etching the preliminary transfer gate electrode (not shown) may include the dry etching process or the wet etching process using a fourth mask pattern M4 formed on the preliminary transfer gate electrode (not shown). The fourth mask pattern M4 may be removed during the etching process or after the etching process. For example, a recess region 200r exposing lateral surfaces (e.g., sidewalls FDs) of the floating diffusion region FD and the floating diffusion pattern 104 may be formed by etching the preliminary transfer gate electrode (not shown). As shown, a distance between the bottom surface 200_{rb} of the recess region 200r and a top surface of the substrate region 102 (e.g., the frontside 102ₐ) in the vertical direction DRv may be equal to or smaller than a distance between the bottom surface FDb of the floating diffusion region FD and the top surface of the substrate region 102 (e.g., the frontside 102ₐ).

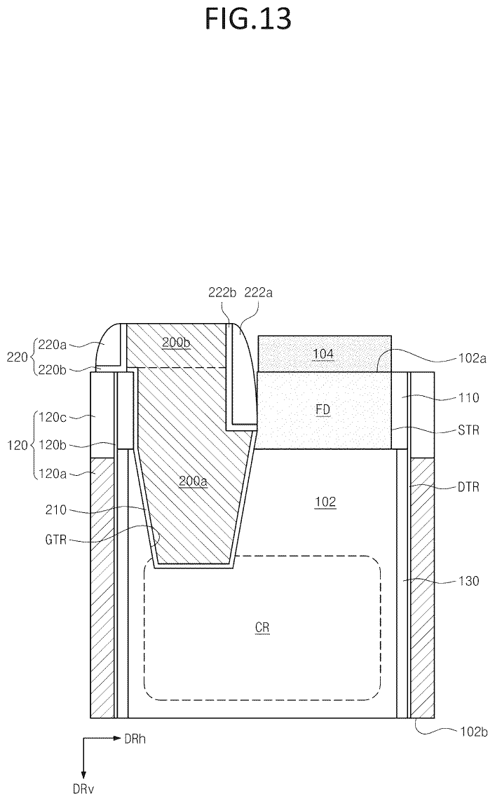

Referring to FIG. 13, a first transfer gate spacer 220 and the second transfer gate spacer 222 may be formed on the lateral surfaces (e.g., opposite sidewalls) of the transfer gate electrode 200. Forming the first transfer gate spacer 220 and the second transfer gate spacer 222 may include sequentially forming a preliminary spacer liner (not shown) and a preliminary spacer capping layer (not shown) on the surface of the transfer gate electrode 200 and etching the preliminary spacer liner (not shown) and the preliminary spacer capping layer (not shown). For example, forming the preliminary spacer liner (not shown) may include depositing silicon oxide (SiOₓ) on the surface of the transfer gate electrode 200. For example, forming the preliminary spacer capping layer (not shown) may include depositing at least one of silicon nitride (SiNₓ), silicon carbide nitride (SiCₓN_{y}), or silicon oxynitride (SiOₓN_{y}) on the preliminary spacer liner (not shown). Etching the preliminary spacer liner (not shown) and the preliminary spacer capping layer (not shown) may be performed until the top surface of the transfer gate electrode 200 is exposed. The top surface of the transfer gate electrode 200 may be exposed between the first transfer gate spacer 220 and the second transfer gate spacer 222. A first spacer cap 220a and a second spacer cap 222a may be spaced apart from the transfer gate electrodes 200 by the first spacer liner 220b and the second spacer liner 222b, respectively. The first spacer liner 220b and the second spacer liner 222b may be extended along lateral and bottom surfaces of the first spacer cap 220b and the second spacer cap 222b, respectively.

Referring to FIGS. 4A and 4B, forming a first wire insulating layer 302 may include depositing an electrically insulating material (e.g., silicon oxide (SiOₓ), silicon nitride (SiNₓ), silicon oxynitride (SiOₓN_{y}), germanium oxide (GeOₓ), germanium nitride (GeNₓ), germanium oxynitride (GeOₓN_{y}), or combinations thereof) on the transfer gate electrode 200, the floating diffusion pattern 104, the device isolation layer 110, and the pixel isolation layer 120. For example, the deposition process may be performed using, for example, the physical vapor deposition (PVD) process, the chemical vapor deposition (CVD) process, or the atomic layer deposition (ALD) process.

Forming a vertical wire 310b may include patterning the first wire insulating layer 302. A sacrificial layer (not shown) may be formed on the first wire insulating layer 302. For example, the sacrificial layer (not shown) may include photoresist. The sacrificial layer (not shown) may be formed by a coating process. The coating process may be performed using, for example, a spin coating, a spray coating, a dip coating, an inkjet printing, or a slot-die coating. Patterning may include an exposure process of irradiating light to a required region of the sacrificial layer (not shown) and a development process of removing either an exposed portion or a non-exposed portion. The first wire insulating layer 302 in a region where the sacrificial layer (not shown) is developed may be etched. Forming the vertical wire 310b may include depositing an electrically conductive material (e.g., at least one of titanium (Ti), tungsten (W), tungsten nitride (WN), tantalum nitride (TaN), titanium nitride (TiN), ruthenium (Ru), niobium nitride (NbN), molybdenum (Mo), cobalt (Co), copper (Cu), aluminum (Al), silver (Ag), or gold (Au)) on the inside and the top surface of the first wire insulating layer 302. The deposition process may be performed using, for example, the physical vapor deposition (PVD) process, the chemical vapor deposition (CVD) process, or the atomic layer deposition (ALD) process. The electrically conductive material may be etched to expose the top surface of the first wire insulating layer 302.

Forming the horizontal wire 310a may include depositing an electrically conductive material (e.g., at least one of titanium (Ti), tungsten (W), tungsten nitride (WN), tantalum nitride (TaN), titanium nitride (TiN), ruthenium (Ru), niobium nitride (NbN), molybdenum (Mo), cobalt (Co), copper (Cu), aluminum (Al), silver (Ag), or gold (Au)) on the first wire insulating layer 302. The deposition process may be performed using, for example, the physical vapor deposition (PVD) process, the chemical vapor deposition (CVD) process, or the atomic layer deposition (ALD) process. Forming the horizontal wire 310a may include patterning an electrically conductive material. A mask pattern (not shown) may be formed on the electrically conductive material. The mask pattern (not shown) may be located on the top surface of the vertical wire 310b. The electrically conductive material exposed by the mask pattern (not shown) may be etched.

Forming the second wire insulating layer 304 may include depositing an electrically insulating material (e.g., silicon oxide (SiOₓ), silicon nitride (SiNₓ), silicon oxynitride (SiOₓN_{y}), germanium oxide (GeOₓ), germanium nitride (GeNₓ), germanium oxynitride (GeOₓN_{y}), or a combination thereof) on the first wire insulating layer 302 and the horizontal wire 310a. The deposition process may be performed using, for example, the physical vapor deposition (PVD) process, the chemical vapor deposition (CVD) process, or the atomic layer deposition (ALD) process.

Forming the microlens 440 may include depositing microlens material on color filters 420. For example, the microlens material may include glass (e.g., silicon-based or chalcogenide-based), thermosetting resin (e.g., polycarbonate-based or polyester-based resin), and photocurable resin (e.g., acrylic resin), epoxy-based, polyurethane-based, or fluoride-based (CaF₂) materials. Depositing the microlens material may be performed using, for example, the physical vapor deposition (PVD) process, the chemical vapor deposition (CVD) process, or the atomic layer deposition (ALD) process.

The present inventive concepts may provide a method of manufacturing an image sensor with improved fill factor and improved charge trapping characteristics and thus having improved functionality (e.g., improved image generating/capturing performance, improved photoelectric conversion efficiency, etc.).

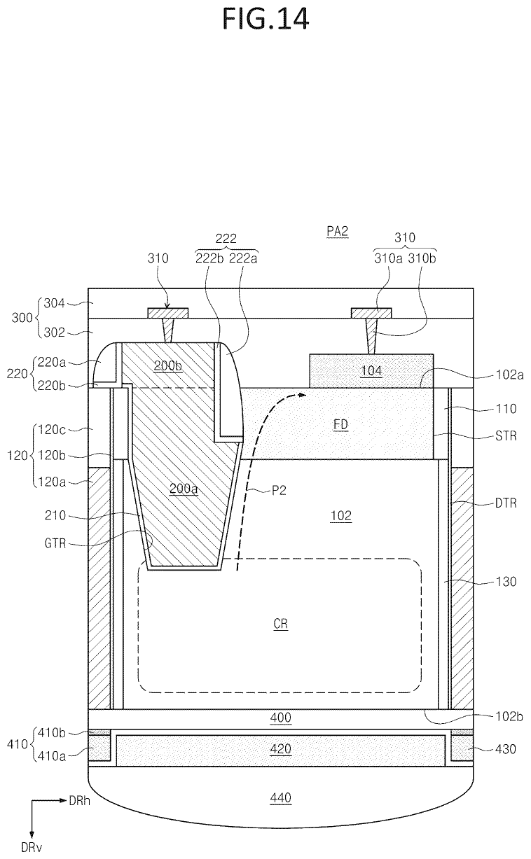

FIG. 14 is a cross-sectional view showing an image sensor according to some example embodiments. For brevity of explanation, features that are the same substantially the same as that described with reference to FIGS. 4A and 4B may not be described.

Referring to FIG. 14, an image sensor PA2 may be provided. Unlike what is explained with reference to some example embodiments, including the example embodiments shown in FIGS. 4A and 4B, charge carriers in a photoelectric conversion region CR may be transferred to a floating diffusion pattern 104 through a second charge transfer path P2. The image sensor PA2 may be understood to be configured to cause the charge transfer path P2 to be formed and/or to define the charge transfer path P2. The second charge transfer path P2 may be formed to pass through a substrate region 102 adjacent to a transfer gate electrode 200 and a frontside 102a of the substrate region 102. For example, a second transfer gate spacer 222 and the floating diffusion pattern 104 may be sufficiently spaced apart to allow the charge carriers to pass through the frontside 102a of the substrate region 102.

Unlike some example embodiments of the present inventive concepts, when the floating diffusion pattern 104 is formed in the substrate region 102, a floating diffusion region FD and the floating diffusion pattern 104 on the frontside 102a may be arranged in a direction away from the second transfer gate spacer 222, for example such that at least a portion of the floating diffusion region FD is between the second transfer gate spacer 222 and the floating diffusion pattern 104 in the horizontal direction DRh. Charge carriers may be transferred to the frontside 102a along a channel formed in a region adjacent to the transfer gate electrode 200, and then reach the vertical wire 310b by passing through the floating diffusion region FD and the floating diffusion pattern 104 along the frontside 102a (e.g., at least partially parallel to the frontside 102a).

Some example embodiments of the present inventive concepts provide the floating diffusion pattern 104 on the substrate region 102 (e.g., protruding from the substrate region 102 and not within the substrate region 102, for example not between the frontside 102a and the backside 102b in the vertical direction DRv), so that a distance between the floating diffusion pattern 104 and the second transfer gate spacer 222 may be smaller than that of the case in which the floating diffusion pattern 104 is formed in the substrate region 102. Accordingly, in some example embodiments of the present inventive concepts, paths in which the charge carriers transfer along the frontside 102a may be shorter than that of the case in which the floating diffusion pattern 104 is formed in the substrate region 102.

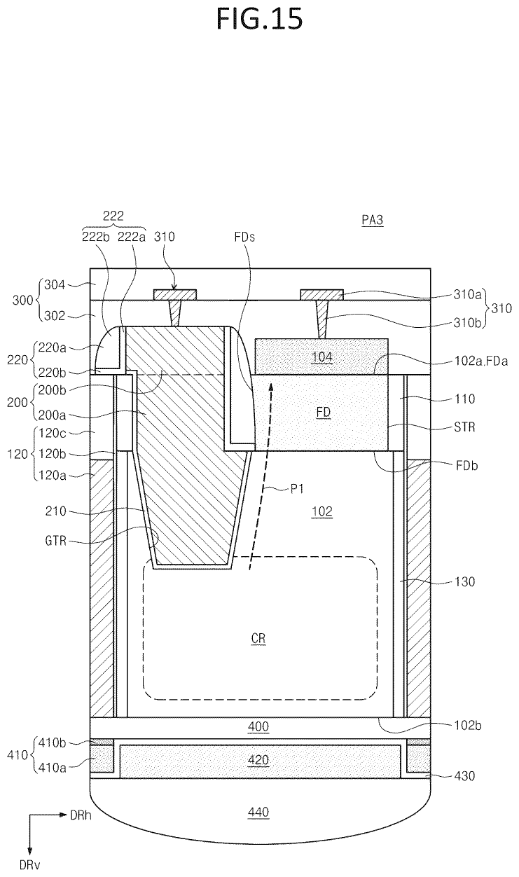

FIG. 15 is a cross-sectional view showing an image sensor according to some example embodiments. For brevity of explanation, features that are the same or substantially the same as that described with reference to FIGS. 4A and 4B may not be described.

Referring to FIG. 15, an image sensor PA3 may be provided. Unlike some example embodiments, including the example embodiments shown in FIGS. 4A and 4B, a second transfer gate spacer 222 may be provided that extends deeply along the vertical direction DRv. In some example embodiments, a floating diffusion region FD may completely overlap the second transfer gate spacer 222 and a frontside 102a along a horizontal direction, for example such that the second transfer gate spacer 222 may contact an entirety of a sidewall FDs of the floating diffusion region FD. For example, the bottom surface of the second transfer gate spacer 222 may be located at the same level as or a lower level than the bottom surface FDb of the floating diffusion region FD. Accordingly, the floating diffusion region FD may be spaced apart from a transfer gate insulating layer 210. As the floating diffusion region FD is formed to be spaced apart from the transfer gate insulating layer 210 and entirely in contact with the second transfer gate spacer 222, gate-induced leakage current may be reduced, minimized, or prevented. In some example embodiments, the second transfer gate spacer 222 may contact at least a top portion of a sidewall FDs of the floating diffusion region FD that extends from the top surface FDa of the floating diffusion region.

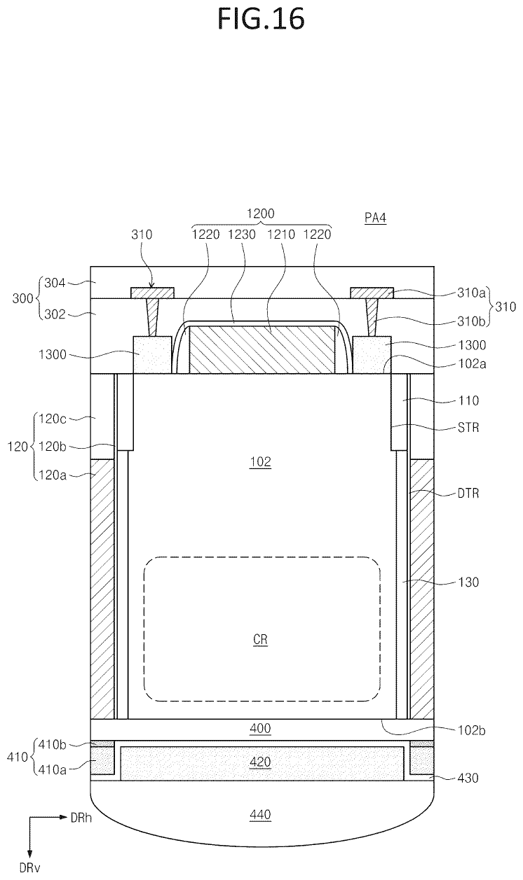

FIG. 16 is a cross-sectional view showing an image sensor according to some example embodiments. For brevity of explanation, features that are the same or substantially the same as that described with reference to FIGS. 4A and 4B may not be described.

Referring to FIG. 16, an image sensor PA4 may be provided. Unlike some example embodiments, including the example embodiments shown in FIG. 4B, a pair of pixel source/drains 1300 may be provided on a substrate region 102 (e.g., not within the substrate region 102 and thus not between the frontside 102a and the backside 102b in the vertical direction DRv), for example such that, as shown in FIG. 16, the pair of pixel sources/drains 1300 include a first pixel source/drain on one lateral surface of the pixel gate electrode 1210 and a second pixel source/drain on another (e.g., opposite) lateral surface of the pixel gate electrode, and where the first pixel source/drain and the second pixel source/drain are both on the substrate region 102. The pair of pixel source/drains 1300 may be disposed adjacent to a pixel gate electrode 1210. As the pair of pixel sources/drains 1300 are formed on the substrate region 102, leakage current due to the short-channel effect may be reduced, minimized, or prevented. Therefore, the present inventive concepts may provide the image sensor PA4 with improved leakage current characteristics and thus having improved functionality (e.g., improved image generating/capturing performance, improved photoelectric conversion efficiency, etc.).

According to the present inventive concepts, an image sensor with improved photoelectric conversion efficiency may be provided.

According to the present inventive concepts, a method for fabricating an image sensor with improved photoelectric conversion efficiency.

While the present inventive concepts have been described with reference to some example embodiments thereof, it will be apparent to those of ordinary skill in the art that various changes and modifications may be made thereto without departing from the spirit and scope of the present inventive concepts as set forth in the following claims.

What is claimed is:

1. An image sensor, comprising:
a substrate region, the substrate region including a photoelectric conversion region;
a transfer gate electrode, the transfer gate electrode including
a buried region within the substrate region, and
a capping region on the buried region;
a floating diffusion region within the substrate region and at least partially overlapping the buried region along a horizontal direction, the horizontal direction parallel to a top surface of the substrate region;
a floating diffusion pattern on the floating diffusion region, the floating diffusion pattern at least partially overlapping the capping region along the horizontal direction; and
a transfer gate spacer between the transfer gate electrode and the floating diffusion pattern.

2. The image sensor of claim 1, wherein the transfer gate spacer is configured to contact the floating diffusion region.

3. The image sensor of claim 1, wherein the floating diffusion pattern is adjacent to the transfer gate electrode such that the image sensor is configured at least partially define a charge transfer path between the photoelectric conversion region and the floating diffusion pattern such that the charge transfer path is configured to extend at least partially vertically in relation to the top surface of the substrate region as the charge transfer path transfers charge carriers from the photoelectric conversion region to the floating diffusion pattern.

4. The image sensor of claim 1, wherein the floating diffusion region has a doping concentration that increases with increasing proximity to the floating diffusion pattern.

5. The image sensor of claim 1, wherein the floating diffusion region completely overlaps the transfer gate spacer along the horizontal direction.

6. The image sensor of claim 1, further comprising a transfer gate insulating layer extending along a lateral surface of the transfer gate electrode,
wherein the transfer gate insulating layer contacts the floating diffusion region.

7. The image sensor of claim 1, further comprising:
a transfer gate insulating layer extended along a lateral surface of the transfer gate electrode,
wherein the transfer gate insulating layer is spaced apart from the floating diffusion region.

8. The image sensor of claim 1, wherein the substrate region and the floating diffusion pattern include different semiconductor materials.

9. The image sensor of claim 1, further comprising:
a pixel transistor, the pixel transistor including
a pixel gate electrode on the substrate region,
a first pixel source/drain on one lateral surface of the pixel gate electrode, and
a second pixel source/drain on another lateral surface of the pixel gate electrode,
wherein the first pixel source/drain and the second pixel source/drain are within the substrate region.

10. The image sensor of claim 1, further comprising:
a pixel transistor, the pixel transistor including
a pixel gate electrode on the substrate region,
a first pixel source/drain on one lateral surface of the pixel gate electrode, and
a second pixel source/drain disposed on another lateral surface of the pixel gate electrode,
wherein the first pixel source/drain and the second pixel source/drain are on the substrate region.

11. A method for manufacturing an image sensor, the method comprising:
forming a substrate region, the substrate region including a photoelectric conversion region;
forming a floating diffusion region at an upper portion of the substrate region;
forming a floating diffusion pattern on the floating diffusion region;
heat treating the floating diffusion pattern;
forming a transfer gate electrode, the transfer gate electrode including
a buried region within the substrate region, and
a capping region on the buried region; and
forming a transfer gate spacer on a lateral surface of the transfer gate electrode, the lateral surface facing the floating diffusion pattern,
wherein the floating diffusion region at least partially overlaps the buried region along a horizontal direction, the horizontal direction parallel to a top surface of the substrate region,
wherein the floating diffusion pattern at least partially overlaps the capping region along the horizontal direction.

12. The method of claim 11, wherein the forming the floating diffusion pattern includes:
forming a preliminary floating diffusion pattern based on etching at least portion of the upper portion of the substrate region; and
implanting impurities into the preliminary floating diffusion pattern.

13. The method of claim 11, wherein the forming the floating diffusion pattern includes:
depositing a preliminary floating diffusion pattern on the substrate region; and
implanting impurities into the preliminary floating diffusion pattern.

14. The method of claim 11, wherein the forming the transfer gate spacer includes:
forming a recess region exposing the floating diffusion region based on etching the transfer gate electrode; and
providing an electrically insulating material into the recessed region,
wherein a bottom surface of the recess region is closer to the top surface of the substrate region than a bottom surface of the floating diffusion region.

15. The method of claim 11, wherein the forming the transfer gate spacer includes:
forming a recess region exposing the floating diffusion region based on etching the transfer gate electrode; and
providing an electrically insulating material to the recessed region,
wherein a distance between a bottom surface of the recess region and the top surface of the substrate region is equal to or smaller than a distance between a bottom surface of the floating diffusion region and the top surface of the substrate region.

16. The method of claim 11, wherein the heat treating the floating diffusion pattern causes the floating diffusion region to have a higher doping concentration with increasing proximity to the floating diffusion pattern.

17. An image sensor, comprising:
a device layer;
a wiring layer electrically connected to the device layer; and
a lens layer configured to focus incident light on the device layer,
wherein the device layer includes
a substrate region having a photoelectric conversion region,
a transfer gate electrode including
a buried region within the substrate region, and
a capping region on the buried region,
a floating diffusion region within the substrate region and at least partially overlapping the buried region along a horizontal direction, the horizontal direction parallel to a top surface of the substrate region,
a floating diffusion pattern on the floating diffusion region and at least partially overlapping the capping region along the horizontal direction, and
a transfer gate spacer between the transfer gate electrode and the floating diffusion pattern.

18. The image sensor of claim 17, wherein
the device layer further includes a pixel transistor, the pixel transistor including
a pixel gate electrode on the substrate region,
a first pixel source/drain on one lateral surface of the pixel gate electrode, and
a second pixel source/drain disposed on another lateral surface of the pixel gate electrode, and
the first pixel source/drain and the second pixel source/drain are on the substrate region.

19. The image sensor of claim 17, wherein the wiring layer and the lens layer are spaced apart from each other with the device layer therebetween.

20. The image sensor of claim 17, wherein the device layer and the lens layer are spaced apart from each other with the wiring layer therebetween.
